(19) United States
(12) Patent Application Publication
(10) Pub. No.: US 2010/0032743 A1
(43) Pub. Date: Feb. 11, 2010

(54) DYNAMIC RANDOM ACCESS MEMORY STRUCTURE, ARRAY THEREOF, AND METHOD OF MAKING THE SAME

(76) Inventors: Jen-Jui Huang, Taoyuan County (TW); Hung-Ming Tsai, Kaohsiung City (TW); Kuo-Chung Chen, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/236,487

(22) Filed: Sep. 23, 2008

(30) Foreign Application Priority Data
Aug. 7, 2008 (TW) 097130021

(51) Int. Cl. H01L 27/108

(52) U.S. Cl. 257/306; 257/E27.084

(57) ABSTRACT

A dynamic random access memory (DRAM) structure has a stacked capacitor disposed above an upper source/drain region of a vertical transistor having a surrounding gate. The gates of each row of a memory array are electrically connected with a buried word line. Each of bit lines is disposed between two adjacent columns of transistors and electrically connected with lower source/drain regions through bit line contacts. The DRAM structure may have a unit cell size of 4F².

### BACKGROUND OF THE INVENTION

1. Field of the Invention

The present invention relates to a dynamic random access memory (DRAM) structure and an array of the DRAM structure, and particularly relates to a DRAM structure including a stacked capacitor, a buried bit line, a surrounding gate, and a vertical transistor.

2. Description of the Prior Art

Along with the miniaturization of various electronic products, the dynamic random access memory (DRAM) elements have to meet the demand of high integration and high density. A DRAM structure includes a capacitor for holding a charge and a transistor for accessing the charge held in the capacitor. DRAMs with trench capacitors or stacked capacitors are widely used in the industry so as to well utilize space of chips to effectively reduce memory cell size. Typically, for trench-type DRAMs, trench capacitors are fabricated inside deep trenches that are formed in a semiconductor substrate by an etching process, followed by the manufacturing process of transistors. That is, the transistors such formed will be not affected by thermal budgets needed for forming the capacitors. However, the miniaturization of the unit trench type capacitor cell is limited by the difficulty of the deeper trench etching technology and the lack of relatively high-k capacitance dielectric material. For stack-type DRAMs, stacked capacitors are relatively easily formed. Generally, after transistors are formed, the stacked capacitors are formed thereon. There are various stack types, such as, plane, pillar, fin-type, and cylinder. The stack-type manufacturing process is more efficient and productive than the trench-type manufacturing process.

Also, there are various types of transistors, which may be categorized into two broad categories: planar transistor structures and vertical transistor structures, based upon the orientations of the channel regions relative to the primary surface of semiconductor substrate. Specifically, vertical transistor devices are devices in which the current flow between the source and drain regions of the devices is primarily substantially orthogonal to the primary surface of the semiconductor substrate, and planar transistor devices are devices in which the current flow between the source and drain regions is primarily parallel to the primary surface of the semiconductor substrate.

Along with the demand of miniaturization of DRAM elements, there is still a need for a novel DRAM structure and an array of the same with a smaller cell unit, higher integration or higher density.

### SUMMARY OF THE INVENTION

One objective of the present invention is to provide a DRAM structure and an array structure thereof. Such DRAM structure may include a stacked capacitor, a buried bit line, a surrounding gate, and a vertical transistor, and it may have a unit cell size of only 4F². F stands for feature size.

The DRAM structure according to the present invention includes a substrate, a transistor, a capacitor, a word line, and a bit line. The substrate has a plane and at least a pillar, and the pillar extends upward from the plane. The transistor includes a gate dielectric layer formed on a vertical wall of the pillar to surround the pillar, a gate material layer disposed on a vertical wall of the gate dielectric layer to surround the gate dielectric layer, an upper source/drain region formed at an upper portion of the pillar, and a lower source/drain region formed in the plane of the substrate in the proximity of a joint of the plane and the pillar. The capacitor is disposed above the upper source/drain region and electrically connected to the upper source/drain region. The word line is formed to contact a vertical wall of the gate material layer, wherein the word line is not above the lower source/drain region. The bit line crosses over the word line and electrically connected to the lower source/drain region.

The DRAM array includes a substrate, a plurality of transistors, a plurality of capacitors, a plurality of word lines, and a plurality of bit lines. The substrate has a plane and a plurality of pillars. The pillars each extend upward from the plane and the pillars form an array. A plurality of transistors is formed on the pillars, respectively. Each transistor includes a gate dielectric layer formed on a vertical wall of the pillar to surround the pillar, a gate material layer formed on a vertical wall of the gate dielectric layer to surround the gate dielectric layer, an upper source/drain region formed at an upper portion of the pillar, and a lower source/drain region formed in the plane of the substrate in the proximity of a joint of the plane and the pillar. The capacitors are disposed above the upper source/drain regions and electrically connected to the upper source/drain regions, respectively. The word lines are formed to contact vertical walls of the gate material layers, respectively. The word lines are not above the lower source/drain regions. The bit lines cross over the word lines and are electrically connected to the lower source/drain regions, respectively.

In comparison to conventional DRAM structures, the DRAM structure according to the present invention includes a buried word line and a vertical transistor having a surrounding gate, and, particularly, in the DRAM array according to the present invention, the unit cell size can be reduced down to only 4F², suitable for a DRAM array with high density.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simple schematic plan view and the corresponding schematic cross-section view of an embodiment of the DRAM structure according to the present invention;

FIG. 2 shows a schematic plan view of the DRAM array according to the present invention;

FIG. 3 shows a perspective view of a part of the DRAM array shown in FIG. 2; and

FIGS. 4-10 show schematic cross-section views illustrating an embodiment of making the DRAM structure according to the present invention.

### DETAILED DESCRIPTION

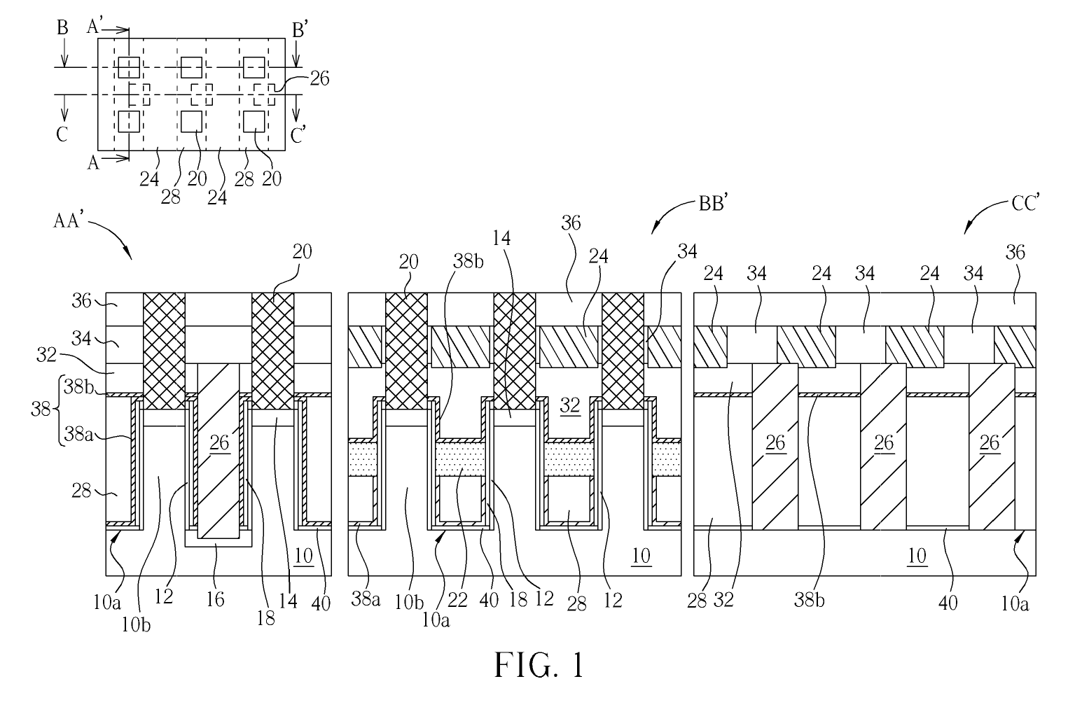

FIG. 1 is a simplified schematic plan view and the corresponding schematic cross-section view illustrating an embodiment of the DRAM structure according to the present invention. As shown in FIG. 1, the DRAM structure according to the present invention includes a substrate 10, such as a semiconductor substrate. The substrate 10 has a plane 10a and a plurality of pillars 10b integrally extending upward from the plane 10a to form an array. Such configuration may be obtained by, for example, carrying out an etching process on a planar substrate through a patterned mask. A vertical transistor is formed between every two adjacent pillars 10b. Each vertical transistor may include a gate dielectric layer 12, an upper source/drain region 14, a lower source/drain region 16, and a gate material layer 18. The gate dielectric layer 12 is formed on a vertical wall of the pillar 10b, such that each pillar 10b is surrounded by the gate dielectric layer 12. The gate material layer 18 is disposed on a vertical wall of the gate dielectric layer 12, such that the gate material layer 18 surrounds the gate dielectric layer 12, for serving as a surrounding gate. The upper source/drain region 14 is formed at an upper portion of the pillar 10b. The lower source/drain region 16 is formed in the plane 10a of the substrate 10 at the proximity of a joint between the plane 10a and the pillar 10b. Accordingly, the surrounding gate of the present invention is a vertical gate. A capacitor 20 is disposed on top of and electrically connected to each of the upper source/drain regions 14. A word line 22 is formed horizontally to contact a part of the vertical wall of the gate material layer 18 and extends to contact the vertical wall of the gate material layer of an adjacent transistor. In such way, the transistors in a row of the array can be connected. The word lines are not right above the lower source/drain regions 16. Bit lines 24 are disposed horizontally and substantially perpendicularly cross over the word lines 22. The bit lines 24 are electrically connected to the lower source/drain regions 16 through bit line contacts 26. Dielectric material or materials is or are filled between/among the components to form, for example, dielectric layers 28, 32, 34, 36, and a bottom trench top oxide (TTO) layer 40. A liner 38, including liners 38a and 38b, may be further formed to surround the gate material layer 18 or cover the upper surface of the word line 22. The liner 38 may serve as a mask for etching, a buffer for stress, and an electric insulator.

It is noted that the word line 22 may contact the gate material layer 18 at any place of the vertical wall of the gate material layer 18, for example, at about central place of the vertical wall, i.e. at about half the height of the vertical wall. The capacitor 20 is not limited to a particular type, and may be a conventional stacked capacitor with a lower electrode plate to contact the upper source/drain region 14 of the transistor.

The bit line contacts 26 are respectively formed on the lower source/drain regions 16 and preferably extend upward to have a height higher than that of a corresponding and adjacent pillar 10b so as to contact the bit lines 24. The bit line contact 26 does not entirely overlap the pillar 10b, but only has a portion to overlap the pillar 10b along the direction of the word line 22. Another portion of the bit line contact 26 extends beyond the pillar 10b to the region of the bit line 24 for the contact with the bit line 24. The bit line 24 is not entirely placed on the bit line contact 26, but only a portion at one side thereof is placed on the portion of the bit line contact 26 beyond the pillar 10b. The bit line 24 shifts a distance from the pillar 10b for leaving a space for the capacitor 20 to be disposed above the upper source/drain region 14. The bit line contact 26 and the gate material layer 18 may be isolated or insulated from each other only by the liner 38.

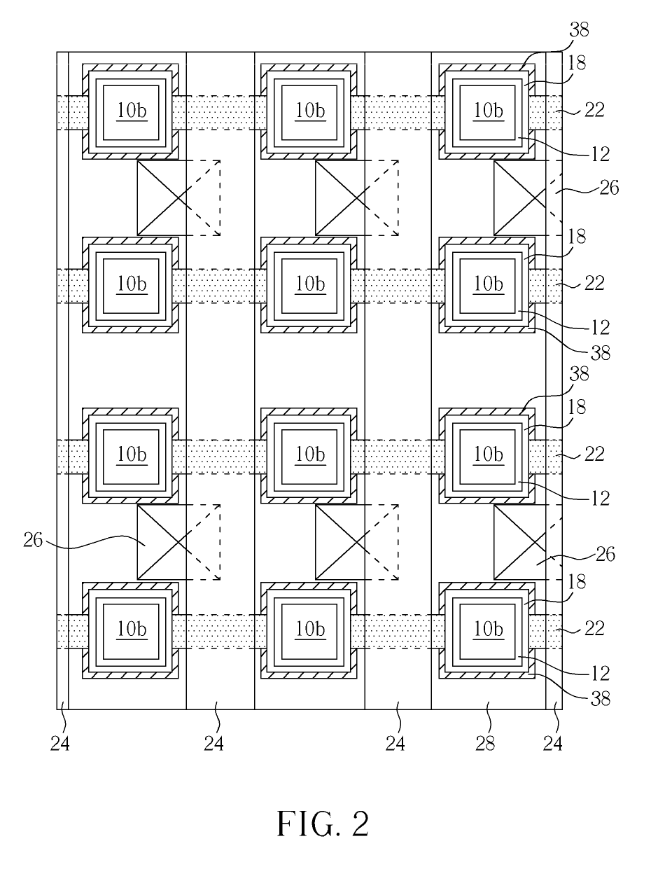

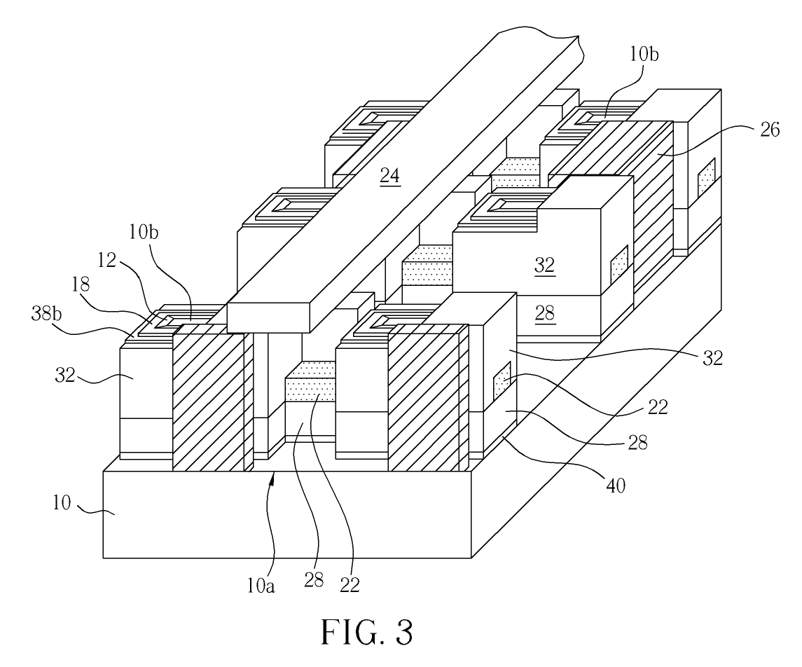

FIG. 2 shows a schematic plan view of a DRAM array formed by the DRAM structure described above. FIG. 3 shows a perspective view of a part of the DRAM array shown in FIG. 2. Capacitors and some dielectric layers and liners are not shown in the drawings for clearly showing specific elements. As shown in FIG. 2, the substrate has a plurality of pillars 10b to form an array. A transistor is formed at each pillar 10b. The transistor has a structure as described above. Transistors in each row are electrically connected through a horizontal word line 22. The word line 22 has a buried structure, with each section disposed between two transistors and contacting the vertical walls of two opposing gate material layers 18 of the two transistors, to accomplish electric connection between two transistors. The bit lines 24 are each horizontally disposed between two columns of the transistors and substantially perpendicularly cross over the word lines 22. The bit lines 24 each are electrically connected to the lower source/drain regions 16 of the transistors through the bit line contacts 26.

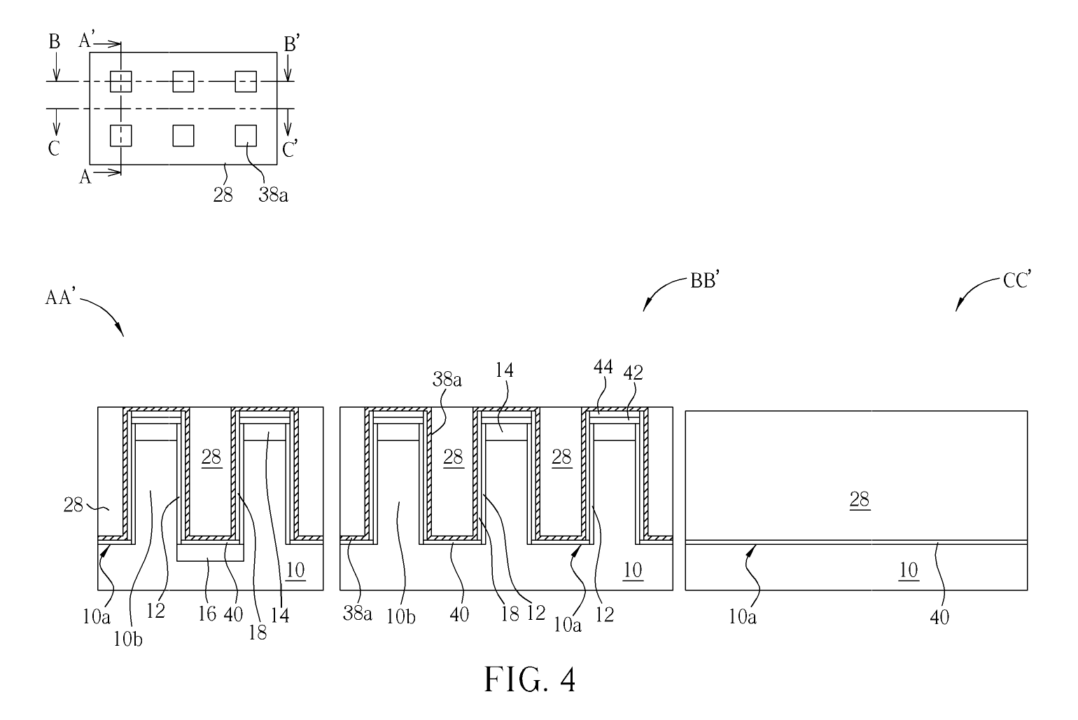

FIGS. 4-10 show schematic cross-section views illustrating an embodiment of making the DRAM structure according to the present invention. Most of the drawings each show a simplified plan view and corresponding cross-section views, for example, a cross-section view taken along line AA′, BB′, CC′ or DD′ shown in the plan views.

First, as shown in FIG. 4, a substrate 10 is provided. A pad oxide 42 and a silicon nitride layer 44 may be deposited. Next, a microlithography process and an etching process are carried out to define active regions and an isolation region for the active regions. The isolation region is in the region of the plane 10a, and the active regions are in the regions of the pillars 10b. In other words, a portion of the substrate is removed by etching process to form the plane 10a, and the portions not removed become the pillars 10b. Thereafter, an implantation process is carried out on the upper portion of the pillars 10b to form the upper source/drain regions 14, and on the plane 10a in the proximity of the place joining the bottom of each pillars 10b to form the lower source/drain regions 16. Thereafter, a deposition process, such as a high density plasma chemical vapor deposition process (HDPCVD), is carried out to form the bottom TTO layer 40 on the plane 10a of the substrate in the isolation region, for electric isolation of the active regions.

Thereafter, the gate dielectric layer is formed. The gate dielectric layer 12, such as a silicon oxide layer, may be formed through a thermal oxidation process on the vertical walls of the pillars 10b. Accordingly, the gate dielectric layer 12 surrounds the pillar 10b. Thereafter, the gate material layer 18 is formed on the vertical wall of the gate dielectric layer 12. Accordingly, the gate material layer 18 surrounds the gate dielectric layer 12. The gate material layer 18 serves as a gate of the vertical transistor, and may include polysilicon. The gate material layer 18 may be formed as follows. A gate material is deposited on the plane of the substrate to fill up until as high as the top of the pillars 10b, and then etching back process is carried out using a mask to leave a desired thickness of the gate material layer on the vertical wall of the gate dielectric layer 12.

Thereafter, a liner 38a is conformally deposited on the substrate to cover the plane 10a (having a bottom TTO layer 40 thereon) and the pillars 10b (having a silicon nitride layer 44 on the top and the gate material layer 18 on the side wall) in a blanket form. Thereafter, a dielectric material is deposited all over to fill the isolation region and cover the pillars 10b, thus forming a dielectric layer 28. The dielectric layer 28 is planarized by, for example, a chemical mechanical polishing (CMP) process until the liner 38a on the pillars 10b is exposed.

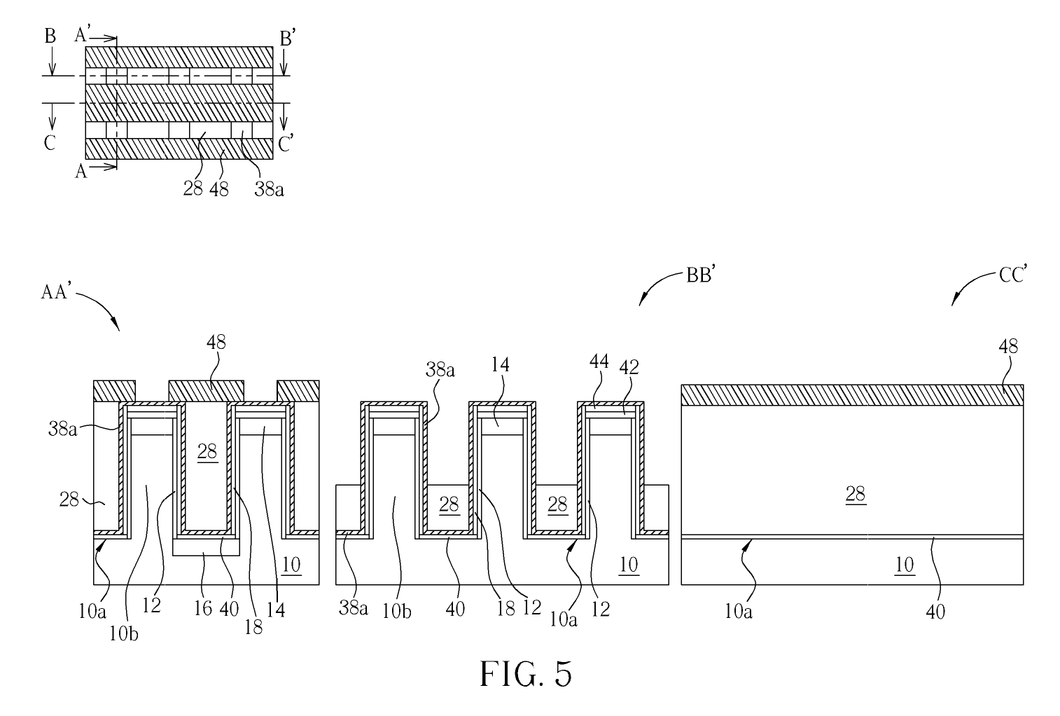

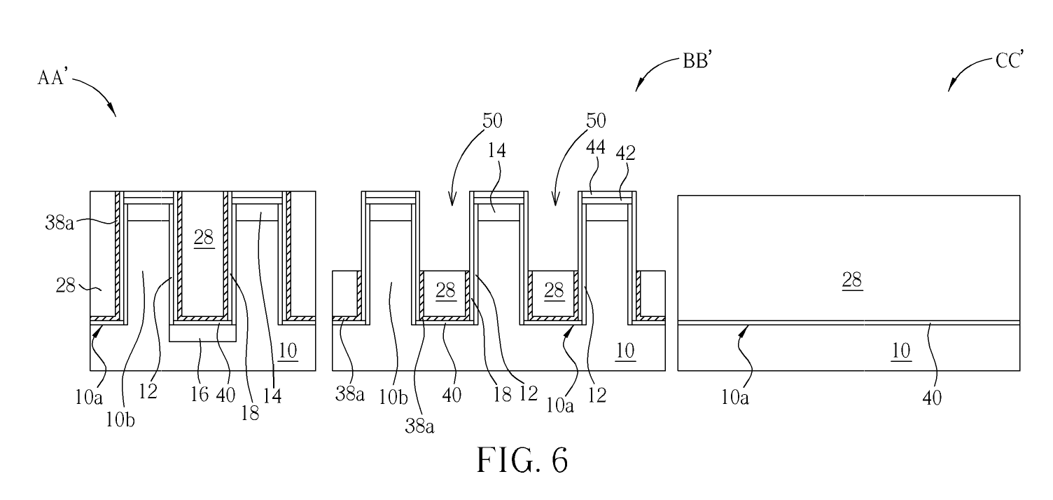

Referring to FIG. 5, the buried word lines 22 are formed. A microlithography process is carried out to form a patterned photo resist layer 48 to expose the word line regions with a predetermined width. An etching process is then carried out to partially remove the exposed dielectric layer in the word line regions (i.e. the dielectric layer 28 between active regions in each row of the array) using the photo resist layer 48 and the liner 38a on the top of the pillars 10b as a mask, to form trenches 50. The depth for etching is not particularly limited as long as the word lines subsequently formed can contact the gate material layers. For example, the depth may be at the half height of the vertical wall of the pillar 10b. After the dielectric layer 28 is partially removed, the liner 38a on the vertical wall is exposed. Thereafter, the photo resist layer 48 is removed. Thereafter, the exposed liner 38a on the vertical wall is removed by, for example, a wet dipping process to expose the upper portion of the two opposing gate material layers 18 on the vertical walls, as shown in FIG. 6.

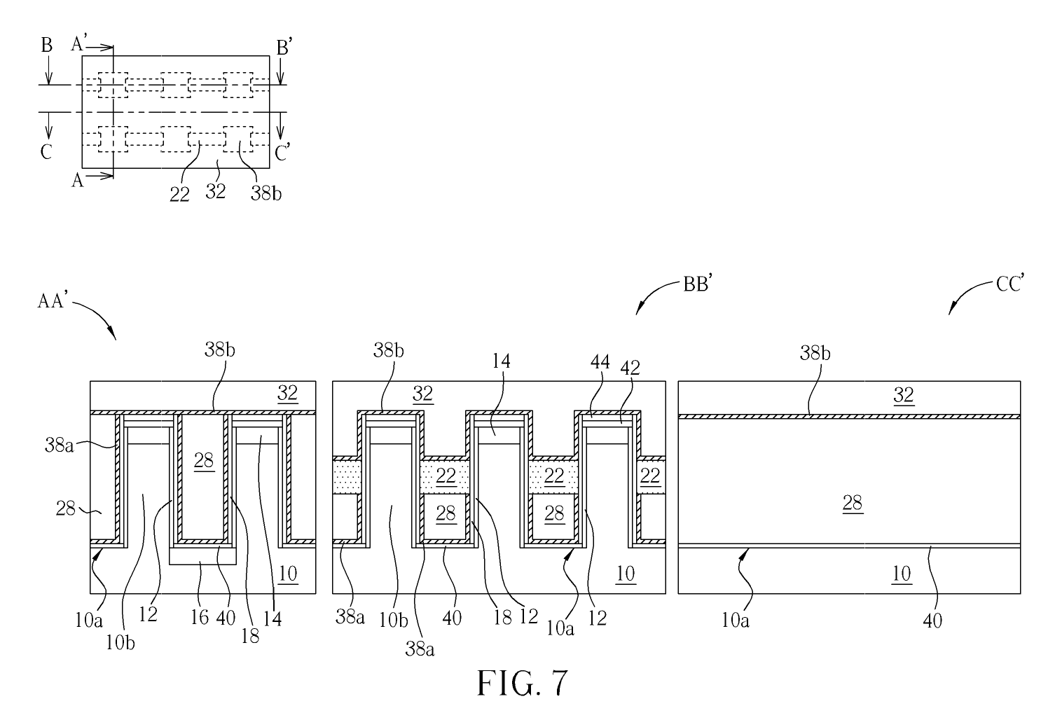

Referring to FIG. 7, a word line material is deposited to fill in the trenches 50 to form word lines 22. The word lines 22 contact two gate material layers 18 of two adjacent transistors, and the gates of the whole row of the transistors can be accordingly electrically connected. A liner 38b is deposited all over to cover the top surface of the word line 22. A dielectric layer 32 (or referred to as interlayer dielectric) is formed all over to fill the trenches 50 and cover the liner 38b. A planarization process is performed to allow the dielectric layer 32 to be higher than the liner 38b.

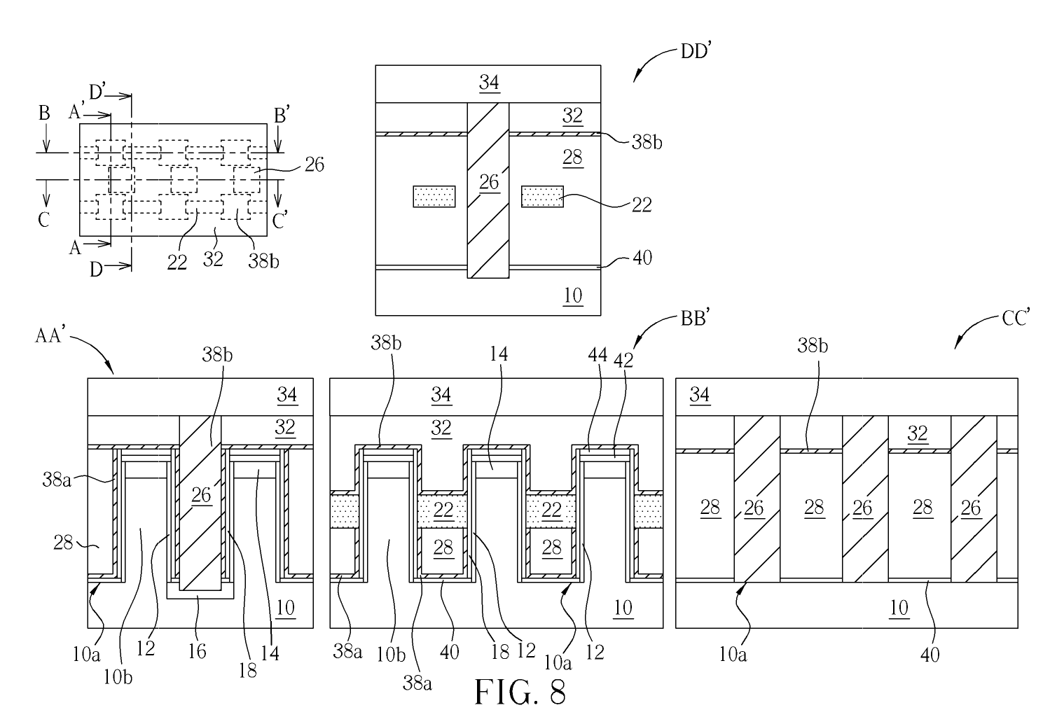

Referring to FIG. 8, the bit line contacts are formed. A microlithography process is carried out to form a patterned photo resist layer to expose predetermined bit line contact regions. The bit line contact regions are located above the lower source/drain regions 16 and do not conflict with the word lines. An etching process is carried out to remove the dielectric layer 32, the liner 38b, and the dielectric layer 28 in the bit line contact regions and to form holes exposing the lower source/drain regions 16. A conductive material is filled in the holes and a CMP process is carried out to form the bit line contacts 26 contacting the lower source/drain regions 16. A dielectric layer 34 (or referred to as interlayer dielectric) is formed all over and planarized. In the embodiment as shown in FIG. 8, each bit line contact region is between the transistor in the first row and the transistor in the second row, or between the transistor in the third row and the transistor in the fourth row, and so on, but not between the transistor in the second row and the transistor in the third row. That is, the lower source/drain region of the transistor in the first row and the lower source/drain region of the transistor in the second row are located in such way that they face to each other and electrically connected to a same bit line through a same bit line contact. These two lower source/drain regions may be connected each other to become as one. It is also noted that the array formed with the DRAM of the present invention is not limited to the layout described herein.

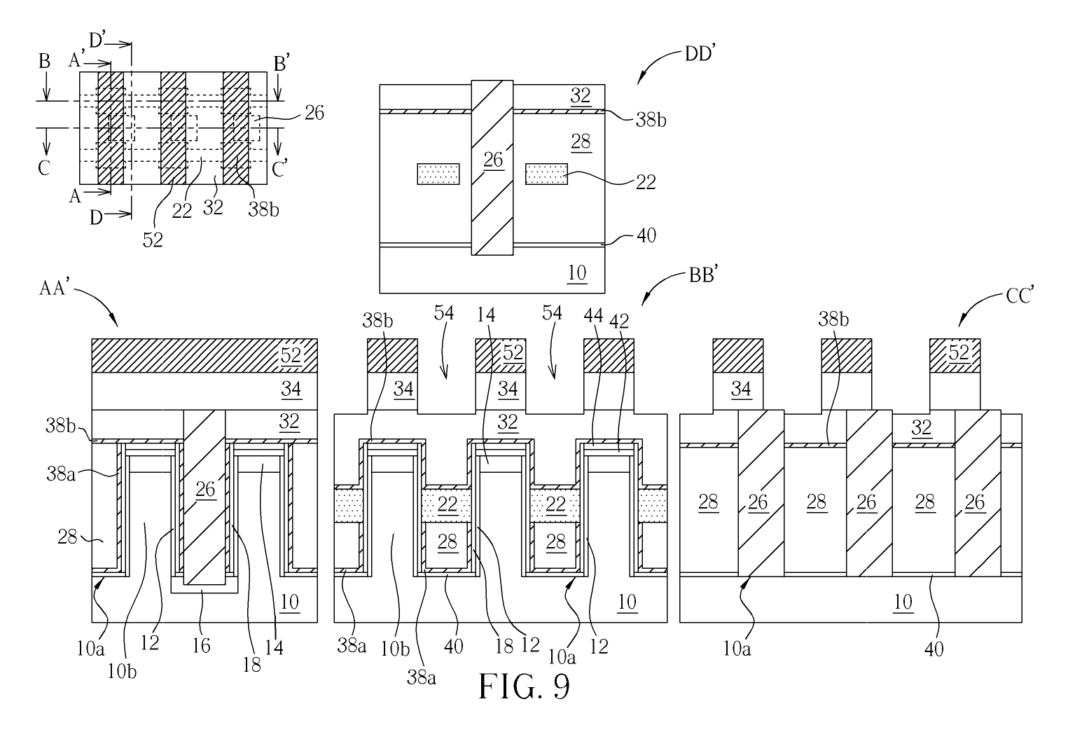

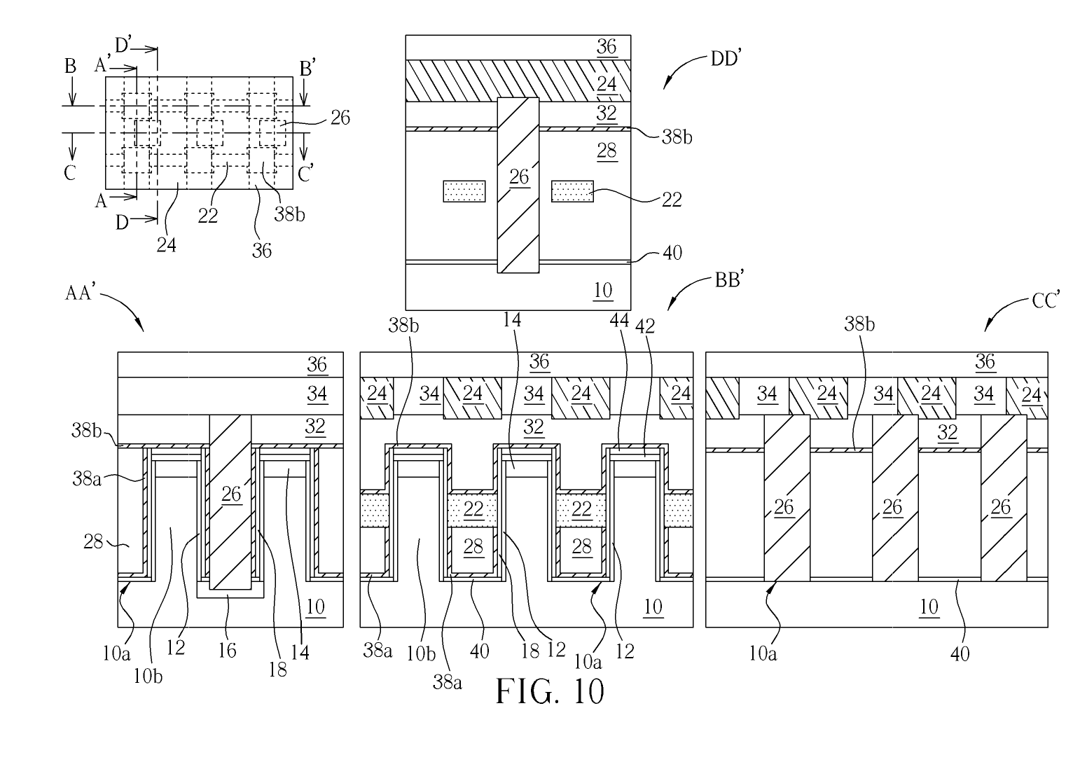

Referring to FIG. 9, the bit lines are formed. A microlithography process is carried out to form a patterned photo resist layer 52 to expose predetermined bit line regions. The bit line regions are located between the transistor in a column and the transistor in an adjacent column of the array. An etching process is carried out to remove the exposed dielectric layer 34 to form trenches 54, until the underlying bit line contacts 26 are exposed. Thereafter, referring to FIG. 10, the photo resist layer 52 is removed, a bit line material is filled in the trenches 54, and then a CMP process is carried out to form the bit lines 24 contacting the bit line contacts 26.

Referring to FIG. 1, capacitors are formed. The dielectric layer 36 (or referred to as interlayer dielectric) is formed all over the dielectric layer 34 and the bit line 24 and planarized. A microlithography process is carried out to form a patterned photo resist layer to expose predetermined capacitor regions. The capacitor regions are located above the pillars 10b. An etching process is carried out to remove the exposed dielectric layer 36, the underlying dielectric layer 34, dielectric layer 32, and liner 38b to form holes exposing the underlying upper source/drain regions 14. The photo resist layer is removed, and capacitors 20 are formed in the holes. The capacitors may be as conventional capacitors, such as, a stacked capacitor having an upper and a lower electrode plates and a dielectric layer therebetween. The capacitors may be formed using conventional techniques. The lower electrode plates of the capacitors are electrically connected to the upper source/drain regions 14 of the transistors, to form the DRAM structure according to the present invention in the embodiment as shown in FIG. 1 and the array.

Those skilled in the art will readily observe that numerous modifications and alterations of the device and method may be made while retaining the teachings of the invention.

What is claimed is:

1. A dynamic random access memory (DRAM) structure, comprising:
a substrate having a plane and at least a pillar extending upward from the plane of the substrate;
a transistor comprising:
a gate dielectric layer formed on a vertical wall of the pillar to surround the at least one pillar,
a gate material layer disposed on a vertical wall of the gate dielectric layer to surround the gate dielectric layer,
an upper source/drain region formed at an upper portion of the pillar, and
a lower source/drain region formed in the plane of the substrate in the proximity of
a joint between the plane and the pillar;
a capacitor disposed above the upper source/drain region and electrically connected to the upper source/drain region;
a word line formed to contact a vertical wall of the gate material layer, wherein the word line is not above the lower source/drain region; and
a bit line crossing over the word line and electrically connected to the lower source/drain region.

2. The DRAM structure of claim 1, wherein the bit line is electrically connected to the lower source/drain region through a bit line contact.

3. The DRAM structure of claim 2, wherein the bit line contact is formed on the lower source/drain region and extends upward to have a height higher than that of the pillar and to contact the bit line, and the bit line contact has a first portion overlapping the pillar and a second portion extending beyond the pillar.

4. The DRAM structure of claim 3, wherein the bit line is partly on the second portion of the bit line contact to leave a space for the capacitor to be disposed above the upper source/drain region.

5. The DRAM structure of claim 1, further comprising a liner covering the gate material layer.

6. The DRAM structure of claim 4, further comprising a liner covering the gate material layer.

7. The DRAM structure of claim 6, wherein the bit line contact is isolated from the gate material layer only by the liner.

8. The DRAM structure of claim 1, further comprising a liner covering an upper surface of the word line.

9. A dynamic random access memory (DRAM) array, comprising:
a substrate having a plane and a plurality of pillars extending upward from the plane of the substrate to form an array;
a plurality of transistors formed on the pillars respectively, each transistor comprising:
a gate dielectric layer formed on a vertical wall of one of the pillars to surround the one of the pillars,
a gate material layer disposed on a vertical wall of the gate dielectric layer to surround the gate dielectric layer,
an upper source/drain region formed at an upper portion of the one of the pillars, and
a lower source/drain region formed in the plane of the substrate in the proximity of
a joint of the plane and the one of the pillar;
a plurality of capacitors disposed above the upper source/drain regions and electrically connected to the upper source/drain regions, respectively;
a plurality of word lines formed to contact vertical walls of the gate material layers respectively, wherein the word lines are not above the lower source/drain regions; and
a plurality of bit lines crossing over the word lines and electrically connected to the lower source/drain regions through a plurality of bit line contacts, respectively.

10. The DRAM array of claim 9, wherein,
a first transistor, a second transistor, a third transistor, and a fourth transistor of the transistors are arranged successively in a column of the DRAM array;
a lower source/drain region of the first transistor and a lower source/drain region of the second transistor face to each other and are both electrically connected to a first bit line of the bit lines through a first bit line contact of the bit line contacts, wherein, the first bit line contact is formed between the first transistor and the second transistor, one portion of the first bit line contact overlaps gate material layers of the first transistor and the second transistor with a first and a second liners formed therebetween, respectively, another portion of the first bit line contact is beyond the first and the second liners along the direction of the word lines, and the first bit line contact is higher than the first and the second transistors;
a lower source/drain region of the third transistor and a lower source/drain region of the fourth transistor face to each other and are both electrically connected to the first bit line through a second bit line contact of the bit line contacts, wherein, the second bit line contact is formed between the third transistor and the fourth transistor, one portion of the second bit line contact overlaps gate material layers of the third transistor and the fourth transistor with a third and a fourth liners formed therebetween, another portion of the second bit line contact is beyond the third and the fourth liners along the direction of the word lines, and the second bit line contact is higher than the third and the fourth transistors; and
no bit line contacts are formed between the second transistor and the third transistor.

11. The DRAM array of claim 9, wherein the width of the pillars, the width of the bit lines, and the width of the bit line contacts each are 1 feature size.

12. The DRAM array of claim 9, wherein the bit line contacts are formed on the lower source/drain regions and extend upward to be higher than the pillars and to contact the bit lines, respectively, and the bit line contacts each have a first portion overlapping one of the pillars and a second portion beyond the one of the pillars.

13. The DRAM array of claim 12, wherein the bit lines each are partly on the second portions of the bit line contacts to leave spaces for the capacitors to be disposed above the upper source/drain regions.
